(19) United States
(12) Patent Application Publication
(10) Pub. No.: US 2015/0059819 A1
(43) Pub. Date: Mar. 5, 2015

(54) SOLAR POWER GENERATION DEVICE

(71) Applicant: Panasonic Corporation, Osaka (JP)

(72) Inventors: TSUYOSHI NOMURA, Kyoto (JP); MASANORI MINAMIO, Osaka (JP); KOUJI ARAI, Nara (JP); KENICHIRO MASE, Osaka (JP)

(21) Appl. No.: 14/468,311

(22) Filed: Aug. 25, 2014

(30) Foreign Application Priority Data
Aug. 30, 2013 (JP) 2013-179039
Aug. 30, 2013 (JP) 2013-179040

(51) Int. Cl. H02S 10/10

(52) U.S. Cl. CPC H01L 31/0583
USPC 136/206

(57) ABSTRACT

In a solar power generation device concentrating solar light to solar cells by a reflecting mirror and converting solar energy into electric energy, a cooling pipe is arranged above the reflecting mirror, a thermoelectric conversion element is mounted on at least one side surface of the cooling pipe and a solar cell is mounted on an upper surface of the thermoelectric conversion element.

### BACKGROUND OF THE INVENTION

1. Technical Field

The present invention relates to a solar power generation device converting solar energy into electric energy.

2. Description of Related art

There is a solar power generation device, as a related-art example, converting solar energy into electric energy by collecting solar light by a reflecting mirror to solar cells arranged on a cooling pipe (for example, refer to Patent Literature 1).

In the solar power generation device described in Patent Document 1, solar energy is converted into electric energy by collecting solar light reflected by a reflecting mirror 301 to a solar cell 302 as shown in FIG. 12. In this case, as the solar light includes heat rays, the solar cell 302 is heated and the temperature thereof is increased. Accordingly, in the solar power generation device described in Patent Document 1, a thermoelectric conversion element 304 is disposed between the solar cell 302 and a cooling pipe 303, and thermoelectric conversion is performed by utilizing the temperature difference between the solar cell 302 and the cooling pipe 303, thereby improving power generation efficiency.

### CITATION LIST

### Patent Literature

Patent Literature 1: JP2004-271063A

### SUMMARY OF THE INVENTION

According to an embodiment of the present invention, there is provided a solar power generation device including a polygonal cylindrical cooling pipe, plural thermoelectric conversion elements installed on respective side surfaces of the cooling pipe, plural solar cells installed on the thermoelectric conversion elements respectively and an insulation covering side surfaces of the solar cells and the thermoelectric conversion elements.

### BRIEF DESCRIPTION OF THE DRAWINGS

FIG. 1 is a perspective view showing a solar power generation device according to Embodiment 1 of the present invention;

FIG. 2 is an A-A cross-sectional view of FIG. 1;

FIG. 3 is an enlarged view of a part “B” of FIG. 2;

FIG. 4 is a perspective view showing a thermoelectric conversion element according to Embodiment 1 of the present invention;

FIG. 5 is an enlarged view of a part “C” of FIG. 3;

FIG. 6 is a schematic view showing part of a power generation unit according to Embodiment 1 of the present invention;

FIG. 7 is a view showing another form of FIG. 4;

FIG. 8 is a partial cross-sectional view of a solar power generation device according to Embodiment 2 of the present invention;

FIG. 9 is a block diagram snowing part of a system configuration of the solar power generation device according to Embodiment 2 of the present invention;

FIG. 10 is a flowchart for explaining the operation according to Embodiment 2 of the present invention;

FIG. 11 is a schematic view snowing the relation between the temperature of the solar cell and power generation efficiency according to the embodiments of the present invention; and

FIG. 12 is a schematic view showing a related-art solar power generation device.

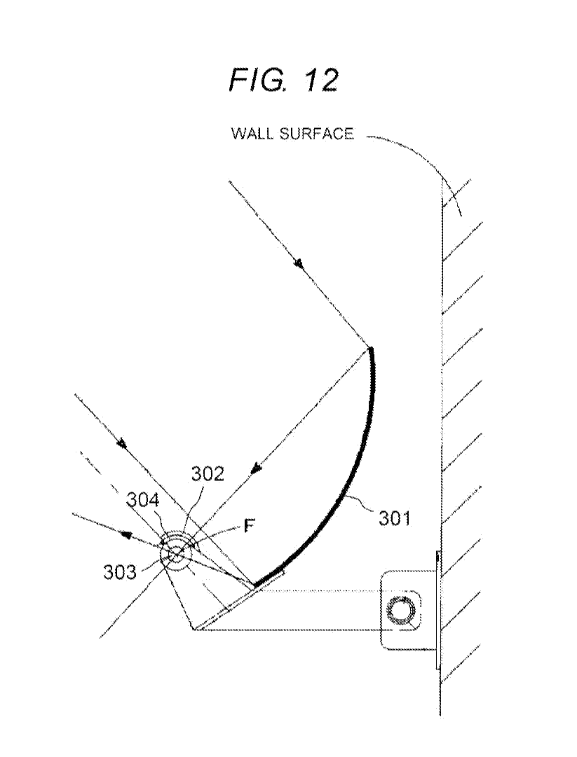

### DESCRIPTION OF EMBODIMENTS

Hereinafter, embodiments of the present invention will be explained with reference to the drawings.

### Embodiment 1

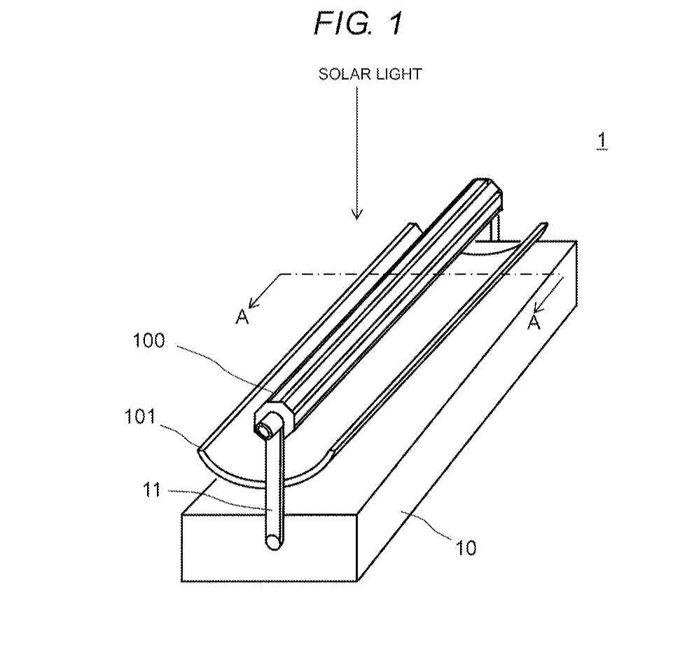

As shown in FIG. 1, a solar power generation device 1 according to Embodiment 1 has a structure of collecting solar light to a power generation unit 100 by a reflecting mirror 101. The reflecting mirror 101 has a semicylinidrical shape in cross section. The power generation unit 100 is arranged in the vicinity of a focal line of the reflecting mirror 101. The reflecting mirror 101 and the power generation unit 100 are supported by a frame 11 provided to stand on a base 10.

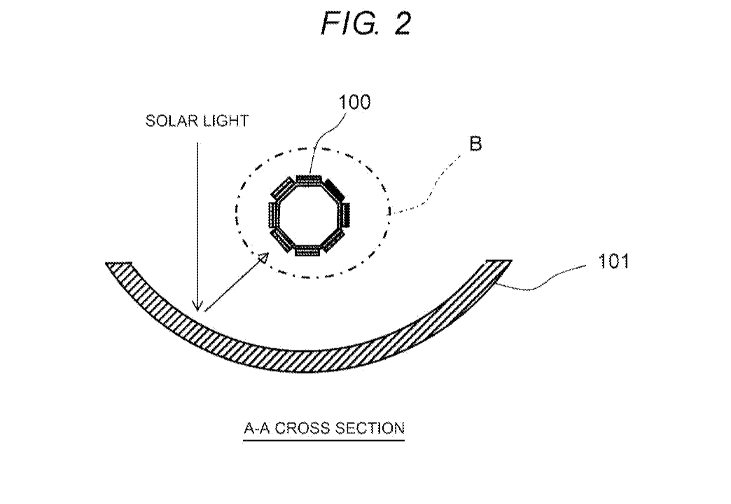

FIG. 2 is a cross-sectional view taken along A-A of FIG. 1. As shown in FIG. 2, the reflecting mirror 101 has a trough shape in which a cross section perpendicular to the longitudinal direction is a semicylindrical shape.

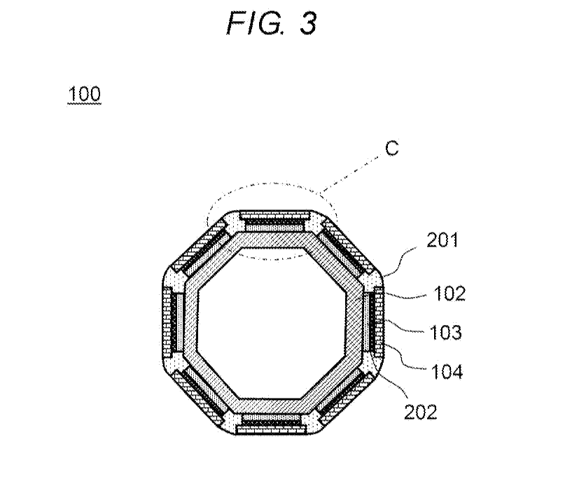

FIG. 3 is an enlarged view of a part “B” of FIG. 2. As shown in FIG. 3, the power generation unit 100 is provided with thermoelectric conversion elements 103 on side surfaces of a cooling pipe 102 and provided with solar cells 104 on upper surfaces of the thermoelectric conversion elements 103. The cooling pipe 102 has a polygonal cylindrical shape a cross section of which is an octagon and has rectangular flat surfaces on side surfaces. Cooling water is circulated inside the cooling pipe 102. The cooling water cools the solar cells 104 through wail surfaces of the cooling pipe 102 and the thermoelectric conversion elements 103. The cooling pipe 102 is an example of a cooling portion. The solar cells 104 are installed on the upper surfaces of the thermoelectric conversion elements 103 through a paste 202. The paste 202 is, for example, a highly-thermal conductive paste having highly thermal conductive characteristics.

The solar cells 104 according to the embodiment are cooled by the cooling water flowing in the cooling pipe 102 through the thermoelectric conversion elements 103. Moreover, thermal energy is converted into electric energy in the thermoelectric conversion elements 103 due to the temperature difference generated between the solar cells 104 and the cooling pipe 102 as the thermoelectric conversion elements 103 are interposed therebetween, as a result, a power generation amount can be increased.

Effects of cooling the solar cells 104 will be explained. As shown in FIG. 1 and FIG. 2, solar light is reflected by the reflecting mirror 101 and collected to the power generation unit 100. As the solar cells 104 are disposed on the surface of the power generation unit 100, the collected solar light is converted from solar light energy into electric energy by the solar cells 104. The solar light collected by the reflecting mirror 101 has a high energy density and includes heat rays, therefore, the surface temperature of the solar cells 104 installed so as to face the reflecting mirror 101 may be increased to the vicinity of 200° C. in the summer season. It is known that power generation efficiency of the solar cells 104 is reduced as the temperature is increased. For example, a material of the solar cells 104 is crystalline silicon, the power generation efficiency is reduced approximately 4% when the temperature in a photoelectric conversion portion of the solar cell 104 is increased 10° C. That is, it is desirable to cool the solar cells 104 when the power generation efficiency is reduced in the case where the temperature of the solar cells 104 is increased in the solar power generation device 1. Accordingly, an apparatus with stable power generation efficiency can be realized by providing the cooling pipe 102 as in the solar power generation device 1 according to the embodiment.

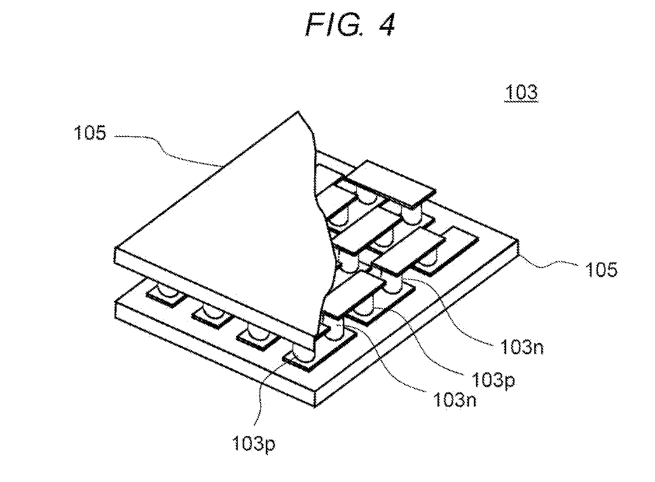

The thermoelectric conversion element 103 is a device converting thermal energy into electric energy. The thermoelectric conversion element 103 is formed by mounting a P-type thermoelectric conversion element 103p in which Sb or the like is added as a dopant to an alloy of a bismuth telluride system and an N-type thermoelectric conversion element 103n in which Se or the like is added as a dopant on a wiring substrate 105 so as to be electrically connected in series. The thermoelectric conversion element 103 is formed by the wiring substrates 105 in which upper and lower surfaces thereof are flat as shown in FIG. 4. Since the cooling pipe 102 has the polygonal cylindrical shape having flat surfaces on side surfaces, the contact area between the cooling pipe 102 and the thermoelectric conversion element 103 becomes large when the thermoelectric conversion element 103 is installed on the side surface of the cooling pipe 102. Accordingly, heat generated on the surface of the solar cell 104 is efficiently transmitted to the cooling pipe 102 through the thermoelectric conversion element 103.

The solar cells 104 are made of crystalline silicon or crystalline compound semiconductors, amorphous silicon and so on. The solar cells 104 directly convert light energy into electric energy by using a light electromotive force of the semiconductor.

An insulation 201 is arranged between adjacent two solar cells 104 as well as between adjacent two thermoelectric conversion elements 103, respectively. As shown in FIG. 3, the insulation 201 is packed, for example, so as to completely fill in a space between adjacent two solar cells 104 as well as a space between two thermoelectric conversion elements 103. It is desirable that the insulation 201 is packed so as not to protrude from the surface of the solar cell 104. This is because, if the insulation 201 protrudes from the surface of the solar cell 104, solar light is reflected by the insulation 201 and concentrated to part of the solar cell 104, which may hasten the deterioration of the solar cell 104.

The insulation 201 according to the embodiment functions as an insulative heat insulating material as well as functions as an antireflection member. That is, the insulation 201 blocks heat transmission between adjacent two solar cells 104 as well as prevents reflection of solar light incident between adjacent two solar cells 104, thereby suppressing occurrence of scattered light.

As the insulation 201 functions as the heat insulating material and the heat transmission between adjacent two solar cells 104 is prevented, heat of the solar cells 104 is transmitted to the cooling pipe 102 efficiently through the thermoelectric conversion elements 103 arranged on undersurfaces of the solar cells 104. Accordingly, cooling efficiency by the cooling pipe 102 can be increased as the insulation 201 functions as the heat insulating material.

Here, materials for the insulation 201 are, for example, insulative heat insulating materials mainly made of calcium sulfate, calcium silicate, glass wool and so on.

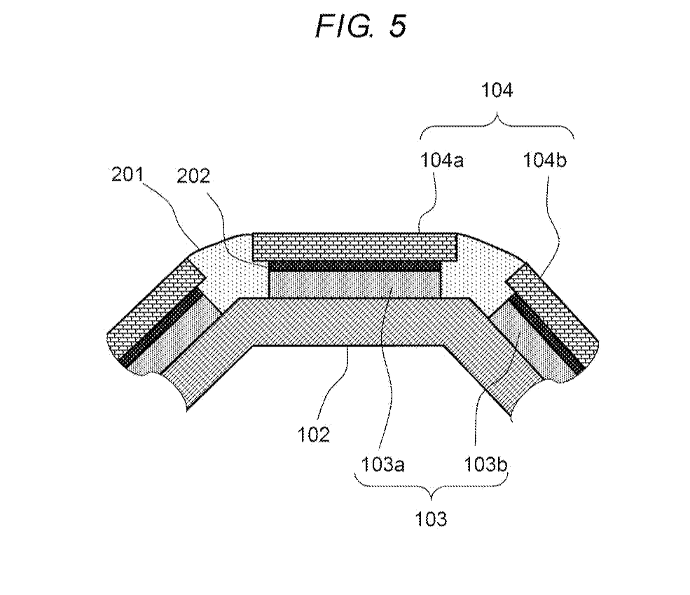

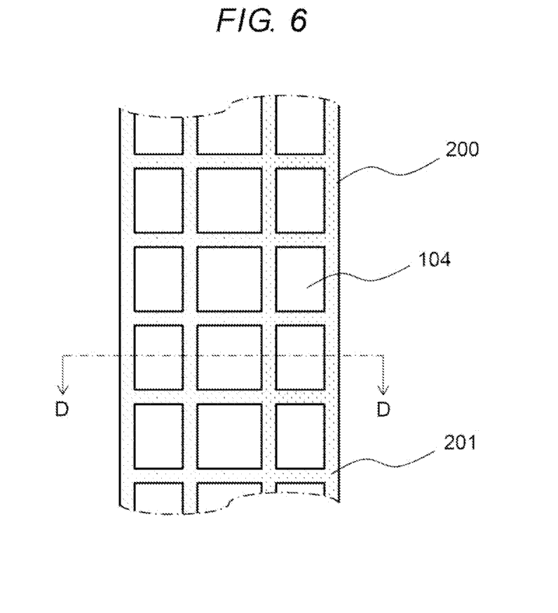

FIG. 5 is an enlarged view of a part “C” of FIG. 3. FIG. 5 is also a cross-sectional view taken along D-D of FIG. 6, which shows part of the power generation unit 100. As shown in FIG. 5, the solar cell 104 has a larger area than the thermoelectric conversion element 103, the solar cell 104 has a protruding portion 114 protruding from an end surface of the thermoelectric conversion element 103. Due to the protruding portion 114, a distance between a solar cell 104a and a thermoelectric conversion element 103b arranged on an undersurface of an adjacent solar cell 104b becomes long, therefore, neat of the solar cell 104a is not easily transmitted to the thermoelectric conversion element 103b. Then, an under surf ace of the thermoelectric conversion element 103b is not easily affected by the heat of the solar cell 104a, therefore, the temperature difference between an upper surface and the under surface of the thermoelectric conversion element 103b becomes large and a generation amount of electric energy in the thermoelectric conversion element 103b is increased.

Moreover, as the insulation 201 is packed between adjacent two solar cells 104 as well as the solar cells 104 have the protruding portions 114 protruding from end surfaces of the thermoelectric conversion elements 103, it is possible to prevent infiltration of moisture such as rainwater into the thermoelectric conversion elements 103.

The cooling pipe 102 is formed so as to be rotated around the central axis with respect to the longitudinal direction thereof. As the cooling pipe 102 is rotated, a position of the solar cell 104 facing the reflecting mirror 101 and a position of the solar cell 104 not facing the reflecting mirror 101 can be exchanged. As the solar cell 104 facing the reflecting mirror 101 receives the collected solar light having high energy density, the deterioration may proceeds more rapidly than in the solar cell 104 not facing the reflecting mirror 101. Accordingly, the lifetime of the solar power generation device 1 can be extended by exchanging the positions of the solar cell 104 facing the reflecting mirror 101 and the solar cell 104 in the counter side periodically by rotating the cooling pipe 102.

Also in the solar power generation device 1 according to the embodiment, the thermoelectric conversion elements 103 and the solar cells 104 are disposed so as to be divided with respect to side surfaces of the cooling pipe 102, the thermoelectric conversion elements 103 and the solar cells 104 are not required to have a large area. Accordingly, yields of thermoelectric conversion elements 103 and the solar cells 104 can be increased, and they can be easily replaced in the case of deterioration, therefore, the solar power generation device 1 having excellent maintainability can be provided.

It is sufficient that the insulation 201 covers side surfaces of the solar cell 104 and the thermoelectric conversion element 103 when considering only heat-insulation performance. In this case, the insulations 201 are coated on the side surfaces of the solar cells 104 and the thermoelectric conversion elements 103 in advance, thereby simplifying manufacturing processes. Additionally, when a gap exists between adjacent two insulations 201, a layer (air layer) formed by air with high heat insulation performance is formed in the gap, which further increases the heat insulation performance between the solar cell 104 and the adjacent thermoelectric conversion element 103.

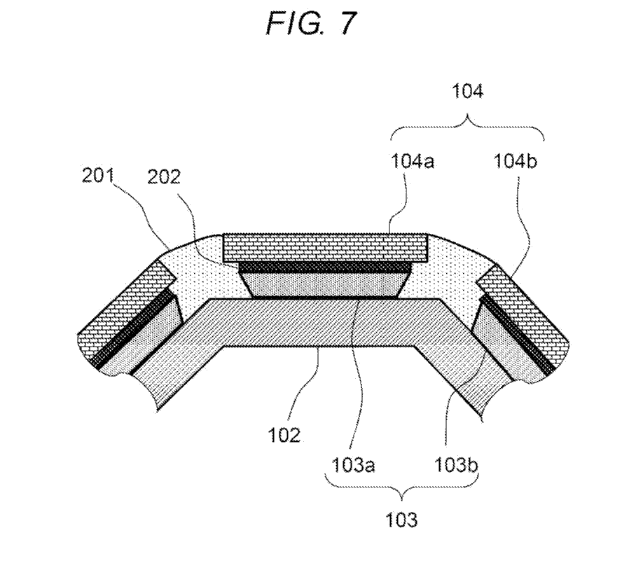

In order to stabilize heat distribution between adjacent two thermoelectric conversion elements 103, as shown in FIG. 7, the thermoelectric conversion elements 103 preferably have a trapezoid shape which becomes gradually small from the solar cell 104 side toward the cooling pipe 102 side. Due to such trapezoid shape, side surfaces of adjacent thermoelectric conversion elements 103 are parallel to each other and heat distribution between them can be stabilized.

The reflecting mirror 101 may be formed by combining many flat mirrors as well as may be formed by combining a plurality of parabolic reflecting mirrors.

It is desirable that the reflecting mirror 101 is directed to a direction directly facing the solar light for utilizing solar energy at the maximum, and a tracking device may be used for following the movement of the sun.

The cooling pipe 102 preferably has a polygonal cylindrical shape having fiat side surfaces, for example, polygonal cylindrical shapes such as a triangular shape and a square shape in cross section.

### Embodiment 2

A solar power generation device 201 according to Embodiment 2 is the same as Embodiment 1 shown in FIG. 1 in the entire structure of the device, however, a power generation unit 200 differs from the power generation unit 100.

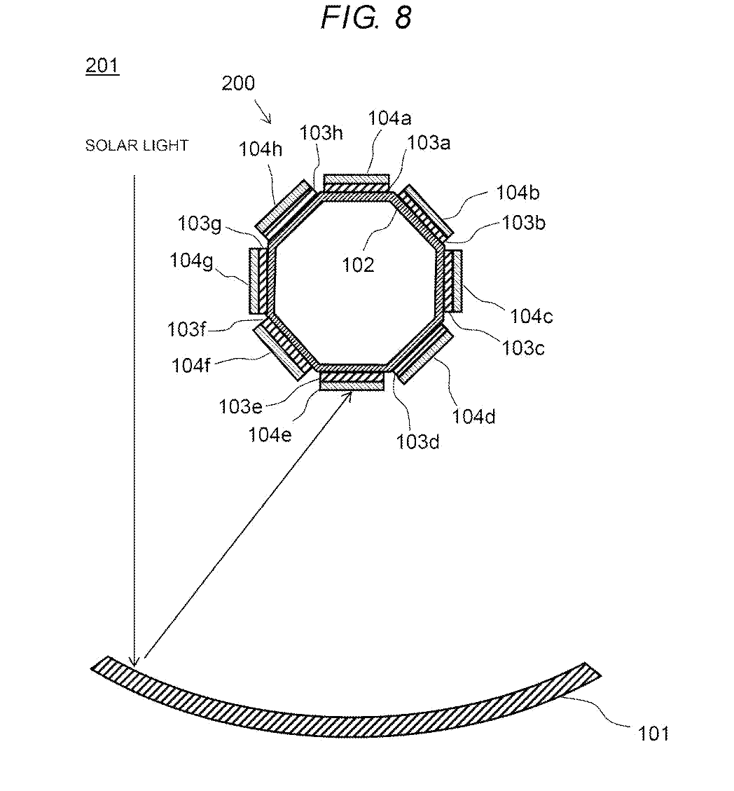

FIG. 8 is a cross-sectional view of the power generation unit 200. As shown in FIG. 8, the power generation unit 100 has a cooling pipe 102, thermoelectric conversion elements 103 (103a to 103h) installed on side surfaces of the cooling pipe 102 and solar cells 104 (104a to 104h) respectively installed on upper surfaces of the thermoelectric conversion elements 103.

The solar power generation device 201 according to the embodiment can increase the power generation efficiency of the solar cells 104 by switching functions of the thermoelectric conversion elements 103 between a power generation function and a cooling function based on the temperature of the solar cells 104, which will be described in detail. Specifically, the solar power generation device 201 according to the embodiment measures the temperature of the solar cells 104 to determine whether the temperature is equal to or lower than a set temperature or not. When the temperature of the solar cell 104 is equal to or lower than the set temperature, the solar power generation device 201 uses the thermoelectric conversion element 103 as the power generation function to thereby increase the power generation amount, and when the temperature of the solar cell 104 is higher than the set temperature, the solar power generation device 201 uses the thermoelectric conversion element 103 as the cooling function to thereby prevent the reduction of power generation efficiency. As a result, the power generation efficiency of the entire solar power generation device 201 can be increased.

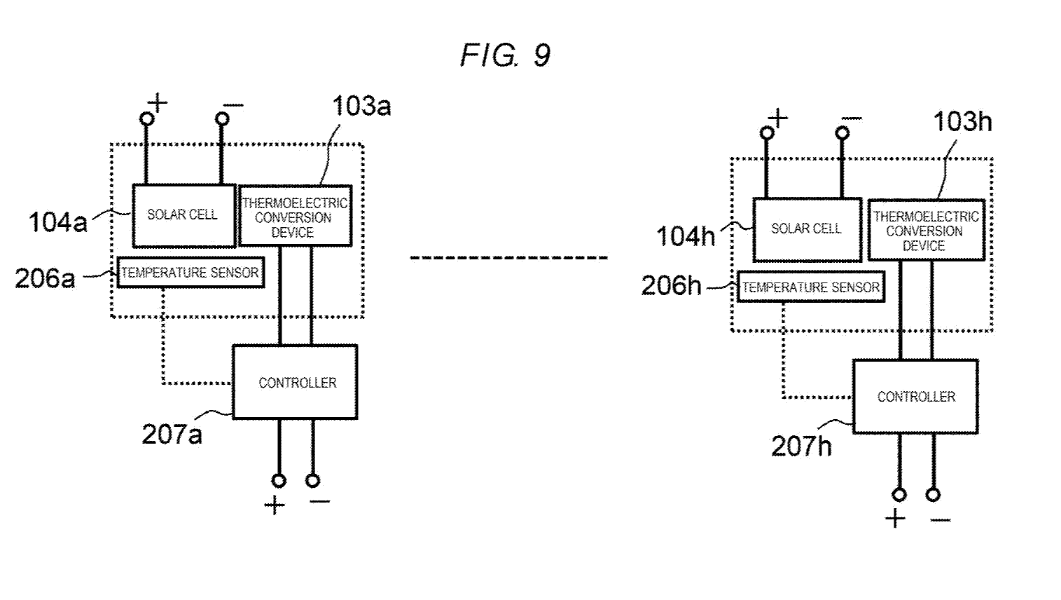

FIG. 9 is a block diagram showing part of a system configuration of the solar power generation device 201 according to Embodiment 2. As shown in FIG. 9, the solar power generation device 201 includes temperature sensors 206 (206a to 206h) and controllers 207 (207a to 207h). The temperature sensors 206a to 20 6h are provided for measuring temperatures of the solar cells 104a to 104h respectively so as to correspond to respective solar cells 104. As the temperature sensor 206, for example, a thermocouple can be used, which can be provided by being adhered to a back surface or a side surface of the solar cell 104. The controllers 207a to 207h correspond to the respective thermoelectric conversion elements 103a to 103h to control the respective thermoelectric conversion elements 103a to 103h. The controllers 207a to 207h switch functions of respectively corresponding thermoelectric conversion elements 103a to 103h to the power generation function or the cooling function based on the temperature of the solar cells 104a to 104h measured by the temperature sensors 206a to 206h.

That is, the thermoelectric conversion elements 103 according to the embodiment have both Seebeck effect and Peltier effect. The power generation function in the embodiment means a function of generating power by this Seebeck effect. In the embodiment, power generation by Seebeck effect is performed by utilizing the temperature difference between the solar cells 104 heated by solar light and the cooling water circulating in the cooling pipe 102. Here, the Seebeck effect is a phenomenon in which an electromotive force is generated in accordance with the temperature difference by bonding different kinds of metals or semiconductors to give the temperature difference to a bonded portion. The cooling function in the present invention means a function of cooling by utilizing heat absorption action in the Peltier effect. In the embodiment, the heat is transmitted from the solar cells 104 heated by solar light to the cooling pipe 102 by supplying the power to the thermoelectric conversion elements 103 to thereby cool the solar cells 104. Here, the Peltier effect is a phenomenon reverse to the Seebeck effect, in which absorption and release of heat dependent on the direction and size of electric current occur when different kinds of metals or semiconductors are bonded and electric current is allowed to flow.

It is also preferable to calculate temperatures of the solar cells 104a to 104h by measuring voltage values generated by the thermoelectric conversion elements 103a to 103b without using the temperature sensors 206a to 206h. As the temperatures of the solar cells 104 can be measured without the necessity of using the temperature sensors 206a to 206h in this case, the number of components in the solar power generation device 201 can be reduced.

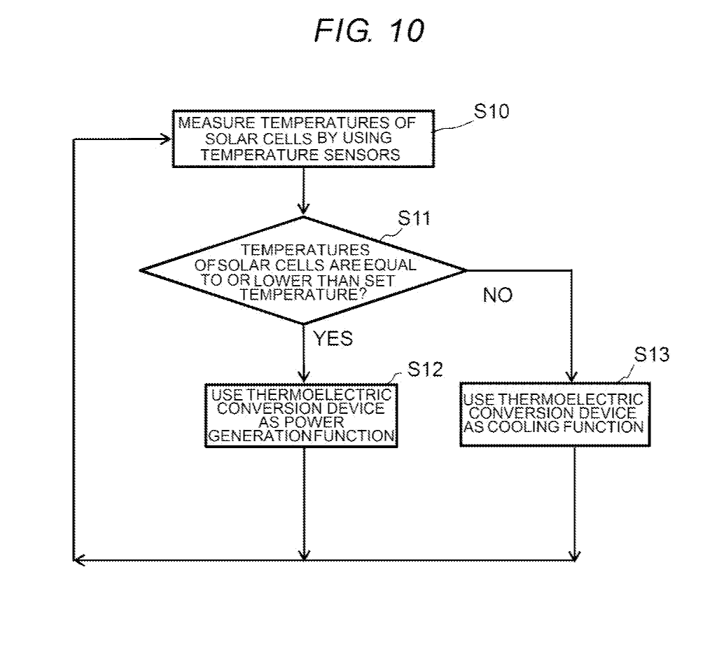

The control performed during the operation of the solar power generation device 201 according to the embodiment will be explained with reference to FIG. 10.

As shown in FIG. 10, the solar power generation device 201 first measures temperatures of corresponding solar cells 104a to 104h by using respective temperature sensors 206a to 206h under control of the controllers 207a to 207h in Step S10.

Next, the solar power generation device 201 determines whether the temperatures of corresponding solar cells 104a to 104h are equal to or lower than the set temperature by the controllers 207a to 207h in Step S11. Here, when the temperatures of the solar cells 104a to 104h are equal to or lower than the set temperature (Yes in S11), the process proceeds to Step S12, where power generation is performed by using corresponding thermoelectric conversion elements 103a to 103h as the power generation function. On the other hand, when the temperatures of corresponding solar cells 104a to 104h are higher than the set temperature (No in S11), the process proceeds to Step S13, where the solar cell 104 is cooled by using the thermoelectric conversion element 103 installed on the undersurface of the solar cell 104 having a higher temperature than the set temperature as the cooling function. For example, when only the temperature of the solar cell 104e is higher than the set temperature, only the thermoelectric conversion element 103e installed on the undersurface of the solar cell 104e is used as the cooling function, and other thermoelectric conversion elements 103a to 103d, and 103f to 103h are used as the power generation function. Accordingly, when the temperature of part of the solar cells 104 is higher than the set temperature, cooling is performed individually only by the corresponding thermoelectric devices 103, thereby performing control in accordance with characteristic variations and states among plural solar cells 104, and uniformizing power generation efficiency of the solar cells 104. As described above, when the temperature of the solar cell 104 is equal to or lower than the set temperature, power generation is performed by utilizing the temperature difference between the solar cell 104 and the cooling pipe 102, therefore, the power generation amount of the entire solar power generation device 201 can be increased.

Here, when the thermoelectric conversion element 103 is used as the cooling function, it is necessary to allow electric current to flow in the thermoelectric conversion element 103 to be operated, as Peltier, therefore, the power generation efficiency of the entire solar power generation device 201 is reduced if an increased amount of the power generation efficiency by the cooling is increased more than electric current to flow. Accordingly, it is required in the present embodiment that a boundary temperature at which an improvement of the power generation efficiency by the cooling in the solar cell is increased more than the electric current to flow in the thermoelectric conversion element is calculated and that the temperature is set in advance as a desired set temperature, for example, by performing an experiment so as to correspond to characteristics of the solar cells to be used.

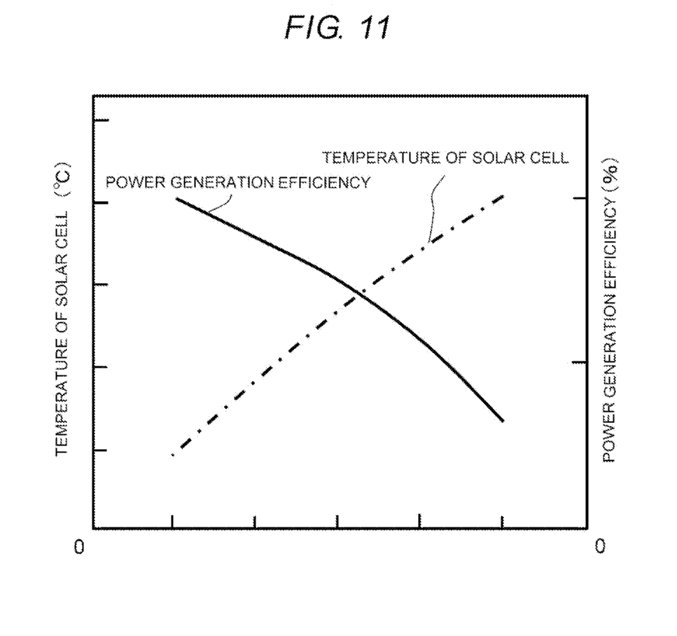

FIG. 11 is a graph showing the relation between the temperature of the solar cell (device temperature) and the power generation efficiency (conversion efficiency) obtained when the thermoelectric conversion element 103 is used as the power generation function. As shown in FIG. 11, when the temperature of the solar cell is increased, the power generation efficiency is reduced. For example, when the material of the solar cell is crystalline silicon, the power generation efficiency is reduced approximately 4% when the temperature of the thermoelectric conversion portion of the solar cell is increased 10° C.

To use the thermoelectric conversion element by switching between the cooling function and the power generation function based on whether the temperature is equal to or lower than the desired set temperature or not as in the present invention is effective also in a solar power generation device not having the reflecting mirror. However, as the power generation efficiency of respective solar cells 104a to 104h can be uniformized in the solar power generation device 201 having the reflective mirror 101, the present invention is preferably applied to the solar power generation device 201 having the reflecting mirror as described above.

if goes without saying that the present invention can be used by combining the above various embodiments.

What is claimed is:

1. A solar power generation device comprising:
a polygonal cylindrical cooling pipe;
plural thermoelectric conversion elements installed on respective side surfaces of the cooling pipe;
plural solar cells installed on the thermoelectric conversion elements respectively; and
an insulation covering side surfaces of the solar cells and the thermoelectric conversion elements.

2. The solar power generation device according to claim 1,
wherein the insulation functions as a heat insulating material.

3. The solar power generation device according to claim 2,
wherein the insulation functions as an antireflection material.

4. The solar power generation device according to claim 1,
wherein the insulation is packed so as to completely fill in a space between adjacent solar cells and adjacent thermoelectric conversion elements.

5. The solar power generation device according to claim 1,
wherein the insulation covers side surfaces of adjacent solar cells and adjacent thermoelectric conversion elements, and an air layer is formed therebetween.

6. The solar power generation device according to claim 1,
wherein the size of each of the solar cells is larger than the size of each of the thermoelectric conversion elements, and
the solar cell has a protruding portion protruding from an end portion of the respective thermoelectric conversion element.

7. The solar power generation device according to claim 1,
wherein each of the plural thermoelectric conversion elements has a trapezoid shape which becomes gradually small from the solar cell side toward the cooling pipe side, and side surfaces of adjacent thermoelectric conversion elements are parallel to each other.

8. The solar power generation device according to claim 1, further comprising:
controllers configured to switch functions of the thermoelectric conversion elements, respectively, between a power generation function and a cooling function based on the temperature of the solar cells.

9. The solar power generation device according to claim 8,
wherein a boundary temperature at which an improvement of power generation efficiency by the cooling in the solar cell is increased more than an electric current to flow in the thermoelectric conversion element is set in advance as a set temperature, and
the controllers control the thermoelectric conversion elements, respectively, as the power generation function when the temperature of the respective solar cell is equal to or lower than the set temperature, and control the respective thermoelectric conversion element as the cooling function when the temperature of the respective solar cell is higher than the set temperature.

10. The solar power generation device according to claim 8,
wherein the controllers are configured to measure the temperatures of the solar cells, respectively, by using voltage values generated by the thermoelectric conversion elements.

11. The solar power generation device according to claim 1, further comprising:
a reflecting mirror arranged below a solar power generation unit at least including the cooling pipe, the thermoelectric conversion element and the solar cell,
wherein the solar power generation unit includes plural thermoelectric conversion elements and plural solar cells corresponding to respective thermoelectric conversion elements.

12. The solar power generation device according to claim 1,
wherein the cooling pipe can be rotated around an axis in a longitudinal direction of the cooling pipe.
